(19) United States
(12) Patent Application Publication
(10) Pub. No.: US 2020/0250360 A1
(43) Pub. Date: Aug. 6, 2020

(54) USE OF DATA FROM FIELD TRIALS IN CROP PROTECTION FOR CALIBRATING AND OPTIMISING PREDICTION MODELS

(71) Applicant: BASF Agro Trademarks GmbH, Ludwighafen am Rhein (DE)

(72) Inventors: Holger HOFFMANN, Langenfeld (DE); Bjoern KIEPE, Langenfeld (DE); Gang ZHAO, Langenfeld (DE); Peter Howard DAVIES, Leverkusen (DE); Hans-Juergen ROSSLENBROICH, Leverkusen (DE); Hubert SCHMEER, Langenfeld (DE)

(21) Appl. No.: 16/639,356

(22) PCT Filed: Aug. 17, 2018
(86) PCT No.: PCT/EP2018/072351

§ 371 Date: Feb. 14, 2020

(30) Foreign Application Priority Data
Aug. 18, 2017 (EP) 17186861.5

(51) Int. Cl. G06F 30/20; G06K 9/00

(52) U.S. Cl. CPC G06F 30/20; G06K 9/00657

(57) ABSTRACT

The present invention is concerned with the control of harmful organisms that can occur when growing crop plants. The present invention provides a method, a computer system and a computer program product that make data obtained in field trials amenable to the calibration and optimization of forecasting models for the attack on plants by harmful organisms and hence allow the development of improved models.

The present invention is concerned with the control of harmful organisms that can occur when growing crop plants. The present invention provides methods of specific recording of field information and methods of calibrating and/or optimizing forecasting models. The present invention additionally provides a computer system and a computer program product that make data obtained in field trials amenable to the calibration and optimization of forecasting models for the attack on fields, field zones or individual plants by harmful organisms and hence allow the development of improved models.

In order to be prepared for attack on crop plants by harmful organisms, it is possible to use forecasting models that forecast the spread of harmful organisms using data and models. These may be models for the contraction of diseases, insect infestation or else weed infestation.

The prediction tool “expert” (http://www.digitalfarming.bayer.com/bdf-timing.html) uses data, for example, relating to the crop (stage of development, growth conditions, crop protection measures), weather conditions (temperature, hours of sunshine, wind speed, precipitation) and pests/diseases (limits of economic viability, pest/disease pressure). With the aid of these data, a field-specific risk of infestation is estimated and a recommendation on time of treatment and crop protection products and an assessment of past crop protection measures is created.

It is very simple for the farmer to call up information. He puts in his ZIP code and his crop (e.g. wheat, barley, rape or potatoes) and the system shows him the days on which the risk of infection is at its highest and favorable or even optimal treatment conditions exist. He can also estimate at a glance the level of probability of an infection.

The suppliers of such prediction tools are constantly further developing their products in order on the one hand to cover more and more harmful organisms and crop plants and in order on the other hand to increase the accuracy of the forecasts and their range into the future.

An essential prerequisite for further development is data that have been generated as far as possible under real conditions.

The technical object of the present invention was that of making high-quality data available simply and efficiently for further development, optimization and/or calibration of prediction tools. More particularly, the data are to be recorded in a specific manner and hence matched to the further development, optimization and/or calibration of prediction tools.

This object is achieved by the subject matter of the independent claims. Preferred embodiments can be found in the dependent claims and in the description that follows.

The present invention firstly provides a method preferably of calibrating and/or optimizing forecasting models, comprising the steps of
optionally providing an application for a mobile computer system for a multitude of users involved in one or more field trials for crop protection products,
users searching for reference fields or trial fields and preferably for recording field information,
users transmitting field information about the reference fields or trial fields, about crop plants grown in the reference fields or trial fields and any harmful organisms present with the aid of the application to a supplier, preferably to a server belonging to a supplier, of forecasts of the attack on crop plants by harmful organisms on the basis of forecasting models,
the supplier correlating the field information transmitted with further data, especially weather data, preferably on the supplier's server,
the supplier calibrating and/or optimizing the forecasting models on the basis of the field information transmitted and further data used for correlation,
the supplier optionally transmitting optimized forecasts, preferably based on the optimized and/or calibrated forecasting model, preferably from the supplier's server, to its customers, preferably to mobile computer systems belonging to its customers.

The present invention further provides a system, preferably for calibrating and/or optimizing forecasting models, comprising

a mobile computer system, preferably for recording field information by means of a first application, and
a server, preferably for providing forecasting models or forecasts of field conditions or for recommendation of agricultural measures,
wherein the mobile computer system is configured such that it assists a user of the computer system in collecting or recording the following field information:
location or geocoordinates of a reference or trial field,
crop plants grown in the reference or trial field,
the nature and extent of harmful organisms that exist in the crop plants at one time or at one or more defined growth stages of the crop plant or of the pest in the growth period, with configuration of the mobile computer system such that it transmits the field information collected or recorded to the server,
   wherein the server is configured to correlate the field information transmitted with further data, especially weather data.

The present invention further provides a computer program product comprising a computer-readable data storage medium and program code or a first application which is stored on the data storage medium and, on execution on a mobile computer system, causes the mobile computer system to execute the following steps:

ascertaining or recording field information relating to
the location or geocoordinates of a reference or trial field,
crop plants grown in the reference or trial field,
the attack on the crop plants by a harmful organism at one time or at one or more defined growth stages of the crop plant or of the pest in the growth period,
transmitting the field information to a server, preferably for providing forecasting models or forecasts of field conditions or for recommendation of agricultural measures.

The invention further relates to a method of specific recording of field information with the aid of a mobile computer system, comprising the steps of:
a) receiving or providing at least one observation point and at least one information protocol assigned to the observation point,
b) activating a specific recording of data based on the information protocol,
c) receiving field information based on the specific data recording according to the information protocol,
d) transmitting or providing the field information received to a server (12).

The invention further provides a method of calibrating and/or optimizing forecasting models, comprising the steps of:
a) receiving or providing an item of field information that has been recorded in a specific manner with reference to an observation point and an information protocol assigned to the observation point,
b) providing a result or a forecast from a forecasting model based on the observation point,
c) determining a difference between the field information assigned to the observation point and the result or the forecast from the forecasting model based on the observation point,
d) generating at least one further observation point and an information protocol assigned to the further observation point if the difference exceeds a threshold,
e) transmitting or providing the at least one further observation point and the information protocol assigned to the further observation point to at least one mobile computer system.

The invention further provides a method of calibrating and/or optimizing forecasting models, comprising the steps of:
a) receiving or providing field information,
b) determining a data density of the field information for multiple classes of field information,
c) generating at least one observation point and an information protocol assigned to the observation point for the class of field information for which the data density is below a threshold,
d) transmitting or providing the at least one observation point and the information protocol assigned to the observation point to at least one mobile computer system.

The invention further relates to a method of generating a forecast of field information or field conditions or for recommendation of agricultural measures, especially of generating a forecast of an attack on crop plants by harmful organisms or of generating an agricultural measure, comprising applying crop protection products, preferably based on a crop protection product requirement, an application time of the crop protection product or an application rate of the crop protection product, said method comprising the steps of:
a) recording field information by one of the methods described herein, where the field information is recorded in a specific or nonspecific manner, and which optionally, in the case of specific or nonspecific recording, optimizes and/or calibrates forecasting models by one of the methods described herein, followed by specific recording of field information by one of the methods described herein,
b) updating the forecasting model based on the field information recorded, where the forecasting model is updated at regular or irregular time intervals, especially during a growing period, based on the field information recorded,
c) generating a forecast based on the updated forecasting model.

The invention further provides a computer program or an application with instructions which, when they are executed on one or more computer(s), especially a local computer system with one or more mobile computer system(s) and/or a server, execute the methods described here. Further provided is a computer program product with instructions stored on a machine-readable data storage medium, wherein the methods described here are executed when the instructions are executed on one or more computer(s), especially a local computer system with one or more mobile computer system(s) and/or a server.

The invention further relates to a mobile computer system for specific recording of field information, comprising:
a) an interface configured to provide or to receive at least one observation point and at least one information protocol assigned to the observation point,
b) an activation module configured to activate specific recording of data on the basis of the information protocol,
c) a recording module configured to record field information on the basis of the specific data recording according to the information protocol,
d) a further interface configured to transmit or to provide the field information received to a server.

The invention further provides a system, especially a server, for calibrating and/or optimizing forecasting models, comprising:
a) an interface configured to provide or to receive an item of field information that has been recorded in a specific manner with reference to an observation point and an information protocol assigned to the observation point,
b) a forecasting module configured to provide a result of a forecasting model based on the observation point,
c) a verification module configured to determine a difference between the field information assigned to the observation point and the result or the forecast from the forecasting model based on the observation point,
d) a generation module configured to generate at least one further observation point and the information protocol assigned to the further observation point if the difference exceeds a threshold,
e) a further interface configured to provide or to transmit the at least one further observation point and the information protocol assigned to the further observation point to at least one mobile computer system.

The invention further provides a system, especially a server, for calibrating and/or optimizing forecasting models, comprising the steps of:
a) an interface configured to receive or to provide field information,
b) a verification module configured to determine a data density of the field information for multiple classes of field information,
c) a generation module configured to generate at least one observation point and an information protocol assigned to the observation point for the class of field information for which the data density is below a threshold,
d) a further interface configured to provide or to transmit the at least one observation point and the information protocol assigned to the observation point to at least one mobile computer system.

The invention further relates to a system for generating a forecast of field information or field conditions or for recommendation of agricultural measures, especially for generating a forecast of an attack on crop plants by harmful organisms or for generating an agricultural measure, comprising applying crop protection products, preferably based on a crop protection product requirement, an application time of the crop protection product or an application rate of the crop protection product, said system comprising:
a) one or more mobile computer system(s) configured to record field information nonspecifically or specifically by the methods described herein,
b) optionally, in the case of specific or nonspecific recording, a system for optimizing and/or calibrating forecasting models, configured to optimize and/or calibrate the forecasting model by one of the methods described herein and to trigger specific recording of field information by the methods described herein,
c) a system for updating the forecasting model, configured to update the forecasting model at regular or irregular time intervals, especially during a growing period, on the basis of the field information recorded and to generate a forecast on the basis of the updated forecasting model.

The invention is explained in detail hereinafter without distinguishing between the subjects of the invention (method, system, computer program, computer program product). Instead, the elucidations that follow are intended to be analogously applicable to all subjects of the invention, irrespective of their context (method, system, computer program, computer program product).

In one embodiment, a first application for recording field information is provided via a network such as the Internet. For instance, the application can be downloaded from a network server on which it has been recorded via a network connection to the mobile computer system.

In a further embodiment, the searching for reference or trial fields comprises the providing of an observation point, especially geocoordinates of a reference or trial field, for user searching of reference or trial fields, wherein the geocoordinates are provided on the mobile computer system and preferably visualized by means of the first application, for example within the scope of a navigation function. It is possible here for the geocoordinates of a reference or trial field to be provided from a database in which reference or trial field data are stored for a given set of reference and trial fields. In addition, time data may be provided as well as the geocoordinates.

In a further embodiment, the field information is recorded by means of the first application on the mobile computer system. Field information can be recorded here in a specific or nonspecific manner. Specific recording of field information can especially be effected here by the methods described here of specific recording of field information with the aid of a mobile computer system.

In a further embodiment, field information about the reference fields or trial fields, about crop plants grown in the reference fields or trial fields and any harmful organisms present is transmitted with the aid of the first application on the mobile computer system to a server belonging to a supplier of forecasts of the attack on crop plants by harmful organisms on the basis of forecasting models.

In a further embodiment, further data, especially weather data, are provided by the supplier on the server for correlation of the field information transmitted with the further data, especially the weather data. It is possible here for the field information to be transmitted to the server together with time data and the geocoordinates of the mobile computer system. Subsequently, the field information can be correlated with weather data via the time data and geocoordinates transmitted.

In a further embodiment, the forecasting models are calibrated and/or optimized by the supplier on the server on the basis of the field information transmitted and for correlation of further data used, such as weather data, wherein the forecasting models are calibrated and/or optimized by the methods described herein of calibrating and/or optimizing forecasting models.

Optionally, an optimized forecast based on the optimized and/or calibrated forecasting model is transmitted by the supplier's server to a further mobile computer system on which a second application for creating forecasts is preferably provided, wherein, further preferably, the second application determines a forecast for the attack on crop plants by harmful organisms on the basis of the optimized and/or calibrated forecasting model.

Preferably, the system for calibrating and/or optimizing forecasting models comprises: a mobile computer system, preferably for recording field information by means of a first application, and

a server, preferably for providing forecasting models or forecasts of field conditions or for recommendation of agricultural measures,
wherein the mobile computer system is configured such that geocoordinates of a reference or trial field are provided for user searching of reference or trial fields on the mobile computer system by means of a first application, and field information is preferably recorded by means of the first application on the mobile computer system, with recording of the following field information:
location or geocoordinates of a reference or trial field,
crop plants grown in the reference or trial field,
the nature and extent of harmful organisms that exist in the crop plants at one time or at one or more defined growth stages of the crop plant or of the pest in the growth period, with configuration of the mobile computer system such that it transmits the field information recorded to the server,
   wherein the server is configured to correlate the field information transmitted with further data, especially weather data.

Preferably, the server is further configured such that forecasting models provided on the server are calibrated and/or optimized on the basis of the field information transmitted and for correlation of further data used on the server. Further preferably, the server is configured such that optimized forecasts based on the optimized and/or calibrated forecasting model are transmitted by the server to a further mobile computer system on which a second application for creating forecasts is preferably provided.

According to the invention, field trials that are conducted for testing of crop protection products are utilized to collect data for the emergence and spread of harmful organisms in crop plants and to utilize these for optimization of forecasting tools. For particular questions, it is also customary to set up untreated fields, part-areas, field strips or small plots with or without repetition in order to estimate the attack of harmful organisms without the use of crop protection products.

A “harmful organism” is understood hereinafter to mean an organism that can appear in the growing of crop plants and can damage the crop plant, adversely affect the harvest of the crop plant or compete with the crop plant for natural resources. Examples of such harmful organisms are weed plants, weed grasses, animal pests, for example beetles, caterpillars and worms, fungi and pathogens (e.g. bacteria and viruses). Even though viruses are not among the organisms from a biological point of view, they shall nevertheless be covered here by the term “harmful organism”.

The term “crop plant” is understood to mean a plant that is purposely grown as a useful or ornamental plant through human intervention.

The term “crop protection product” is understood to mean a composition with which harmful organisms can be effectively controlled and/or their spread can be prevented. A crop protection product is typically a formulation comprising one or more active ingredients against one or more harmful organisms. If the harmful organisms, for example, are weed plants or weed grasses, the active ingredient for control of the weed plants or weed grasses is a herbicide and the crop protection product is a herbicide formulation. If the harmful organisms, for example, are a fungus, the active ingredient for control of the fungus is a fungicide and the crop protection product is a fungicide formulation.

Crop protection products do not necessarily have solely beneficial effects on crop production. Their use can also harbor risks and hazards to man, animals and the environment, especially when they are circulated without testing and without official approval and/or used improperly.

Therefore, new crop protection products in most countries of the world may be circulated only after testing and granting of approval from the authorities. Moreover, the validity of a granted approval is time-limited in most countries, and new testing for renewal of the approval is undertaken at a given time.

The testing of crop protection products is undertaken in field trials inter alia. The aim of a field trial may be, for example, to determine the effect of a crop protection product, to compare the effect with other crop protection products, or to determine an optimal amount of crop protection products or an optimal time for deployment of a crop protection product. Typically, in such field trials, reference fields that have not been exposed to any crop protection product are set up. By comparison of a trial field or field in which a crop protection product has been employed, for example for control of a harmful organism, with the reference field, it is possible to obtain conclusions as to the efficacy of the crop protection product.

The term “field” is understood to mean a spatially delimitable region of the surface of the Earth which is in agricultural use by planting of crop plants in such a field, optionally supplying them with nutrients and optionally harvesting them. A field may be defined by its geographic position and/or the field boundaries.

The term “trial field” is understood to mean a field for field trials that comprises multiple part-areas for different trial sequences according to a trial protocol. For example, the trial sequence may comprise different crop protection products for different part-areas. Alternatively or additionally, the trial sequence may comprise different amounts of the crop protection product or different times for the application of the crop protection product to the different part-areas. A part-area of the trial field may be an untreated part-area that serves as reference field.

The term “reference field” is understood to mean a field or part of a trial field area in which crop plants are planted, and which is used as reference in a field trial for a crop protection product. By contrast with further fields or part-areas of the trial field that are considered within the scope of the field trial, no crop protection products are used in the reference field.

According to the invention, the reference or trial fields are utilized in order to obtain data relating to the spread of harmful organisms under real conditions and to utilize these for optimization, further development and/or calibration of prediction tools.

In order to keep the level of work associated with the obtaining of data low, according to the invention, a first application is provided for a mobile computer system that can be utilized by personnel that are involved in a field trial and have access to a reference or trial field.

The application of the invention is a piece of software that can typically be loaded onto and installed on a mobile computer system from an Internet site and/or an “app store”. Accordingly, the application can be provided via a network such as the Internet. The application can be provided on a server and downloaded to the mobile computer system via the network. In addition, the providing of the application may be linked to an authorization in order to make the application accessible only to a selected group of users. In the present case, the selected group of users may be restricted to authorized personnel within the scope of field trials, in order to assure high reliability in the recording of the data. The mobile computer system may, for example, be a laptop, a notebook or a smartphone. The use of a smartphone as mobile computer system has the advantage that almost everyone nowadays has such a smartphone and carries it constantly with them. A smartphone typically has all the functions and media required to execute the present invention.

Reference or trial fields can be searched for in a guided manner with the aid of position data or geocoordinates. The position data or geocoordinates can be provided by means of a location sensor or a GPS sensor in the mobile computer system. In addition, the target position or the geocoordinates of the reference or trial field can be provided in order to generate a navigation path between the current position data or the current location of the mobile computer system and the target position.

The application of the invention is intended to assist the user in collecting information relating to the reference or trial fields that are regularly searched for in any case in the course of the field trial. More particularly, field information is to be recorded in a specific manner. It is conceivable here that all information or some of the information must be input into the application by the user. The input may be undertaken in the form of a text input. It is conceivable to use pull-down menus from which the user can select the information applicable in the particular case from a list. This has the advantage that the field information can be recorded in standardized form and uniformly. It is also conceivable that the user inputs information by means of speech input. It is conceivable that information is input, for example, via a barcode or a two-dimensional optical code. Also conceivable is the reading-in of information from RFID tags or comparable data storage media. It is conceivable that some information is recorded automatically, for example the date, the time of day and/or the geocoordinates of that position where the user is using the application of the invention.

The application is used to collect preferably the following information or field information:

### Geocoordinates of the Reference or Trial Field

The geocoordinates of the position where the user is present on execution of the application of the invention is preferably detected automatically by means of a GPS sensor which is included nowadays in most smartphones. It is also conceivable that the user records his position on a virtual map.

### Crop

The user is asked to specify the crop plant being grown in a reference or trial field (plant type). It is conceivable that this information is displayed in machine-readable form, for example on an information sign in the field. It is conceivable, for example, that the information about the crop plant being grown in each case is available in the form of an optical code (for example a barcode, data matrix code, QR code or comparable code). In such a case, it is conceivable that the user will use his smartphone to read the optical code by means of the installed camera function and to transmit the information to the application of the invention. It is also conceivable that the user is asked to take a photograph of the crop (for example of a single plant). It is conceivable that the particular crop is detected automatically with the aid of image analysis and object recognition methods. It is conceivable that the automatic recognition is conducted on the user's mobile computer system; it is likewise conceivable that the photographic image is transmitted to an external server, for example by means of the mobile communication network, and analyzed thereon. It is conceivable that the result of the analysis is transmitted to the user.

### Sowing Date

The sowing date can be input by the user, read in from an external source (for example information sign with optical code), or ascertained automatically from the growth stage of the plant from a photographic image with the aid of image analysis methods.

### Soil

The type of soil present and the soil conditioning measures conducted are preferably likewise requested/ascertained by the application of the invention.

### History

It may also be advantageous to find out information about the previous history of the reference or trial field, for example which plants have been grown before and/or which crop protection measures have been undertaken before. These data can be requested from the user or adduced at a later juncture from other sources (for example if the information has already been transmitted to an external server).

### Growth Stage

The growth stage of the plants being grown in the reference or trial field can be input by the user or ascertained automatically from a photographic image with the aid of image analysis methods. It is also possible to transmit forecasts of the growth model from the server to the mobile computer system in order to give the user a clue as to the BBCH stage of the crop and hence to ascertain the optimal juncture for the recording of field information. The forecasts of the growth model are provided to the mobile computer system, for example with the aid of an API interface.

### Harmful Organisms

For the optimization and/or calibration and/or further development of the prediction tool, a matter of particular interest is whether a harmful organism has already spread in the reference or trial field and, if so, to what extent it has already spread. The application thus preferably asks and/or ascertains whether a harmful organism is apparent, which harmful organism it is, how severely the plants have already been affected and how the harmful organism has spread/is spreading (for example in the form of clusters or proceeding from a particular field boundary or the like). This information can also be ascertained using photographic images, for example in order to recognize a harmful organism present and/or to estimate/quantify the severity of an attack.

Once the information has been collected with the aid of the application of the invention, they are transmitted by the mobile computer system to an external server. The transmission is preferably via a mobile communication network. The supplier of the prediction tool has access to this server and can see the data transmitted. It is also conceivable that it is not the supplier itself that has access to the server, but a developer working on behalf of the supplier. It is also conceivable that further personnel is involved in processing and transmitting the data onward.

For simplification, however, the invention is described here as if there were just one instance (the supplier) involved in the development, optimization, calibration and sale of prediction tools or predictions, even though different instances may be involved in reality. This simplification should thus not be regarded as a restriction of the invention.

If the information is on the server, the information transmitted by the user is correlated with further data. The information transmitted includes geocoordinates and time data (date, time). These data may be correlated, for example, with the weather data at the corresponding location at the corresponding time or within a defined period of time before the corresponding time. This correlation makes it clear how the weather evolved in a defined period of time before the time of information collection by the user at the location of the reference or trial field. This information is important since the evolution of the weather typically has a major effect on the spread of harmful organisms. Further correlation with the crop plant grown and any harmful organisms discovered gives information as to the weather conditions under which the harmful organisms have developed and spread on the crop plant present in the present case. This information can be used for matching with existing models, for calibration of existing models, for optimization of existing models and/or for development of new models.

Because the application of the invention is available globally via a Internet page and/or an app store and there are many users involved in field trials, it is possible to collect large amounts of data on different crop plants, weather conditions and harmful organisms.

The supplier of forecasts or prediction tools is thus capable of providing its customers with constantly improved forecasts.

In one embodiment, field information can be provided on the server by the method described here of specific recording of field information with the aid of a mobile computer system. A corresponding local system comprises one or more mobile computer system(s) and the above-described system, especially in the form of the server.

In one embodiment, the observation point specifies geocoordinates and time data. The geocoordinates can specify a defined part-area of a reference or trial field. In addition, the geocoordinates can specify a specific location of one or more individual plants, for example in a defined part-area of the reference or trial field. The geocoordinates can be generated here by a regular or randomized spatial pattern.

The time data can specify a specific time, multiple specific times or a defined frequency of specific times within a growth period. A growth period relates here to a cultivation period in one season, for example to the period between sowing and harvesting. It is possible here for the times to be specified in a regular or randomized manner. In addition, the time may be correlated with the morphological growth stage of the crop plant via the BBCH (Federal Biological Institute, Federal Plant Variety Office and Chemical Industry) code. The specifically defined geocoordinates and time data, by contrast with field information recorded in a nonspecific manner, can reduce scatter in the field information. More particularly, the field information recorded at specific times can be correlated with the BBCH code of the crop plants, and recording can be effected at given BBCH stages.

In a further embodiment, the information protocol specifies the field information to be recorded. The information protocol specifies, for example, that not only the crop but also a growth stage, any recognizable harmful organism and any degree of spread or any spread threshold of an attack by a harmful organism should be recorded. The harmful organism may be a disease, a weed or an insect.

In a further embodiment, the activation is based on the observation point and/or the corresponding information protocol. For example, the activation is based on a current time and/or current position data from the mobile computer system in relation to the observation point. In a further embodiment, the activation comprises a navigation function that uses position data from the mobile computer system to generate a navigation path to the observation point and especially to geocoordinates defined therein. In addition, a navigation path can be generated for different geocoordinates defined at the observation point. If the geocoordinates specify, for example, a regular or randomized spatial pattern, the navigation path may be generated in sections for each geocoordinate at which field information is to be recorded. For instance, the user can be guided stepwise to the individual geocoordinates where field information is to be recorded. This enables simplified and specific data recording tailored to the further development, optimization or calibration of the forecasting models.

In a further embodiment, the field information is recorded with the aid of the mobile computer system by readout of an optical code, such as a barcode or a QR code, or a transponder, such as an RFID tag. For instance, the crop can be read off via the optical code or the transponder mounted at the reference field, at the trial field or at a part-area of the trial field. In addition, field information can be displayed in accordance with the information protocol for selection, for instance, as a drop-down list on a touch-sensitive display. By detecting a touch at a position on the touch-sensitive display corresponding to the field information displayed, this can be received by the mobile computer system. More particularly, it is possible here to predefine the field information to be selected, such that merely standardized values are selectable by defined criteria. Such a prior selection increases the data quality since the field information is recorded in a uniform manner.

In a further embodiment, the field information is recorded with the aid of the mobile computer system by providing a photographic image and extracting the field information by means of an image analysis method. For instance, photographic images of individual plants can be analyzed for the crop, the growth stage or the attack of a harmful organism. Such image analysis methods may be used, for example, for classification and quantification of diseases, insects or weeds.

In one embodiment, the difference determined between the field information assigned to the observation point and the result from the forecasting model based on the observation point is used to determine a prediction accuracy. In a further embodiment, the forecasting model can be used to forecast field information in normally cultivated fields. By contrast with reference or trial fields, normally cultivated fields are not cultivated according to a fixed framework for field trials, for instance according to a fixed trial protocol. The forecast serves here to generate recommendations for cultivation of the field or agricultural measures such as treatment with crop protection products. It is possible here to transmit the forecast to a mobile computer system, with additional transmission of the prediction accuracy of the forecasting model determined from the difference. The provision of the prediction accuracy makes it possible to provide the user of the forecast with a measure of accuracy of the forecast at any time and hence facilitates the making of decisions based, for example, on the recommended agricultural measures.

In a further embodiment, the forecasting model can be calibrated and/or optimized at regular or irregular intervals, especially during the growth period, on the basis of the field information recorded, with specific or nonspecific recording of the field information. The field information can be provided instantaneously or directly after the recording of the field information and hence in real time. The field information can also be provided with a delay after the recording of the field information if the network connection of the mobile computer system to the server has been interrupted. In this case, the provision is triggered as soon as the network connection has been restored. The instantaneous or direct transmission enables seamless optimization, calibration or updating of the forecasting model on the basis of which a forecast can be generated. For instance, the existing forecasting model and/or the prediction accuracy can be updated in real time, for example by optimizing or adjusting the forecasting model and/or the prediction accuracy in real time immediately after receiving the field information. The update can be effected
with every new item of field information that is provided, and hence in real time at a given frequency,
if differences occur between the field information and the result of the forecasting model based on the observation point and the specifically recorded field information has been transmitted or
if inadequate data density has been detected for any class of field information and the specifically recorded field information has been transmitted,
at defined times within a growing period.

If a difference or inadequate data density has been detected, the update may directly follow the transmission or provision of the specifically recorded field information on the basis of the specifically recorded field information by the methods described herein of calibrating and/or optimizing forecasting models. Thus, further development and improvement of the forecasting models during the growth period is possible.

In one embodiment, observation points and the corresponding information protocols are generated for one or more classes of field information. One class of field information here refers, for example, to such information that specifies the growth stage, the soil type and the attack of a harmful organism. In a further embodiment, observation points and the corresponding information protocols are generated for a class of field information, for example that which specifies the growth stage or the attack of a harmful organism. In a further embodiment, observation points and the corresponding information protocols are generated for multiple classes of field information, for example that which specifies the growth stage and the attack of a harmful organism.

The observation points can be determined using reference or trial field data, such as geographic data, climate zone data, trial protocols, soil data or crop data. In one embodiment, the reference or trial field data comprise geographic data. For example, a reference or trial field may be stored by means of a geocoordinate and a corresponding reference or trial field boundary or by means of a set of geocoordinates that identify the reference or trial field boundary. In addition, field trial-specific data may be recorded as reference or trial field data in the database for a trial field in which a reference field, for example, is located. In addition, reference or trial field data that specify different part-areas of the trial field may be recorded. A specific trial protocol may be assigned to every part-area, for instance a trial sequence with a particular treatment intensity or treatment frequency with crop protection products. In this way, observation points may be generated on the basis of the database comprising reference and trial field data.

### BRIEF DESCRIPTION OF THE FIGURES

Working examples of the invention are detailed in the drawings and elucidated in detail in the descriptions that follow. The figures show:

FIG. 1 an illustrative local computer system comprising a server and a mobile computer system,

FIG. 2 an illustrative method of specifically recording field information,

FIG. 3 an illustrative method of calibrating and/or optimizing forecasting models based on field information that has been recorded specifically,

FIG. 4 a further illustrative method of calibrating and optimizing forecasting models based on field information that has been recorded specifically.

### BRIEF DESCRIPTION OF THE EMBODIMENTS

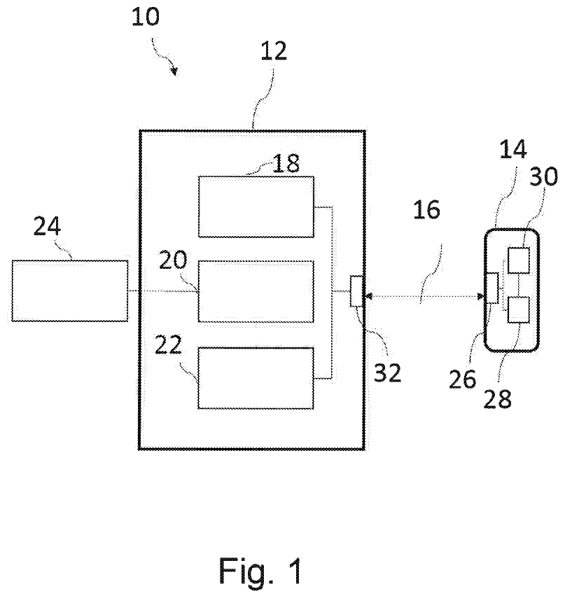

FIG. 1 shows an illustrative local computer system 10 for calibrating and/or optimizing forecasting models, comprising a server 12 and a mobile computer system 14. The server 12 here may be a cloud server that provides IT infrastructure for storage space, computing power or application software. Computer systems 14 such as a desktop computer or mobile computer systems 14 such as a smartphone, a portable digital assistant (FDA), a laptop or a tablet can access the server 12 via a network 16 such as the Internet. More particularly, observation points and information protocols can be communicated from the server 12 to mobile computer systems 14, or field information from mobile computer systems 14 to the server 12.

The mobile computer system 14 comprises:
a communication interface 26 configured to provide at least one observation point and at least one information protocol assigned to the observation point,
an activation module 28 in communication with the interface 26, configured to activate specific data recording based on the information protocol, a recording module 30 in communication with the activation module 28, configured to record field information based on the specific data recording according to the information protocol,
an interface 26 in communication with the recording module 30, configured to transmit the field information received to the server 12.

The server 12 comprises:
a communication interface 32 configured to receive field information recorded in a nonspecific or specific manner or to transmit observation points and the corresponding information protocols to the mobile computer system 14,
a forecasting module 18 configured to provide a result of a forecasting model based on the observation point,
a verification module 20 configured to determine a difference between the field information and the result from the forecasting model or a data density,
a generation module 22 configured to generate observation points and corresponding information protocols when the difference exceeds a threshold or when the data density is below a threshold for a class of field information.

On the server 12, a forecasting module 18 provides forecasting models which, based on crop data such as stage of development or growth conditions, weather data such as temperature, hours of sunshine, wind speed or precipitation, or harmful organism data such as limits of economic viability or harmful organism pressure, provide forecasts of plant growth or of the risk of attack. Such forecasts can also be utilized to recommend agricultural measures such as the application of crop protection products and especially the treatment time, amount and nature of the crop protection product in a growing period. In addition, an assessment of past crop protection measures can be created and the effect thereof on future crop protection measures or yield can be determined.

Based on field information communicated by the mobile computer systems 14 to the server 12, it is possible by means of a verification module 20 to verify and falsify the forecasting models. For example, for a geocoordinate at a time that can be correlated via the BBCH code to the morphological growth stage of the crop plant, field information relating to pest attack can be communicated by the mobile computer system 14 to the server 12. Using this field information, the result of the forecasting model relating to pest attack for the geocoordinate communicated and the time communicated can be compared with the field information recorded relating to pest attack. It is possible here to correlate the field information recorded with further data. For instance, weather data for the geocoordinate communicated and the time communicated can be called up, for instance, from an external database 24 accessed by the server 12 and can be included in the forecast. If a difference arises between the result of the forecasting model and the field information recorded, it is possible by means of the generation module 22 to specifically generate further observation points and information protocols and communicate them to one or more mobile computer systems 14. For instance, it is possible to specifically record further field information with which the forecasting model can be further developed and improved.

In order to generate further observation points and information protocols, reference field data or trial field data are provided on the server 12 or in a separate database 24 accessed by the server 12. For example, available reference fields or trial fields are recorded in the database via their respective geocoordinates. Geocoordinates may comprise coordinates of the field boundary or a base coordinate and a field boundary shape associated therewith. As well as the geocoordinates, trial protocol data, soil data or data relating to the climate region may additionally be recorded for the available reference fields or trial fields. On the basis of these reference field data or trial field data, it is possible to generate observation points and information protocols.

In addition, field information stored on the server or in a separate database 24 accessed by the server can be verified by means of the verification module 20 with regard to the quality of the data set. For example, the field information stored can be verified with regard to the amount of data for different geocoordinates, growth stages or weather conditions. If a quantitative deviation is found for a class of field information in that a small amount of data is available for a climate region, for a range of growth stages or for particular weather conditions, it is possible by means of the generation module 22 to specifically generate further observation points and information protocols and communicate them to one or more mobile computer systems 14. For instance, it is possible to specifically record further field information with which the forecasting model can be further developed and improved.

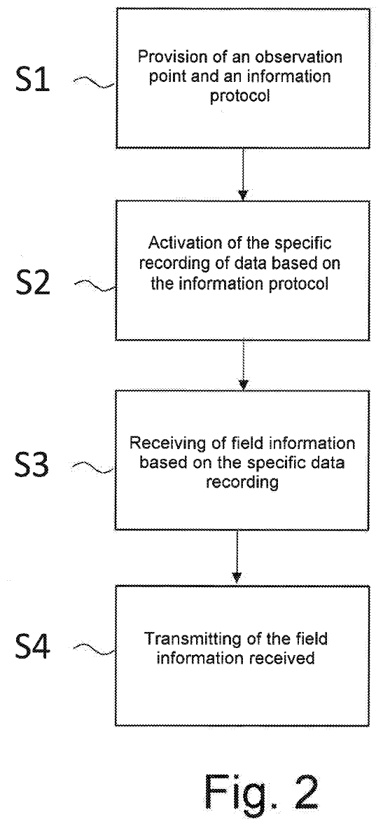

FIG. 2 shows an illustrative method of specifically recording field information recorded with the aid of a mobile computer system 14.

In a first step S1, at least one observation point and at least one information protocol assigned to the observation point are provided on the mobile computer system 14. These may have been transmitted by the server 12 and provided at the interface 32. The observation point preferably specifies geocoordinates and time data. For example, the geocoordinates specify part of the reference or trial field area. Alternatively, the geographic data may specify one or more locations of a crop plant in the reference or trial field. The time data may specify a specific time in a growth period that may be correlated via the BBCH code to the morphological growth stage of the crop plant. The time data may also specify multiple specific times in the growth period. The information protocol preferably specifies the field information to be recorded.

In a second step S2, specific data recording is activated on the basis of the information protocol. The activation can manually by the user, for instance by opening the application. Alternatively, the activation may be automatic, for instance by detection of the current time on the mobile computer system 14 and the current position of the mobile computer system 14. For instance, the current time and current position of the mobile computer system 14 can be provided via integrated sensors or functions of the mobile computer system 14. The position can be detected via a location sensor integrated within the mobile computer system 14, such as a GPS sensor. Preferably, the specific data recording is activated when the geocoordinates and time data provided on the server side agree with the position and time provided on the computer system side within a defined range. For instance, a warning or message can be issued on the mobile computer system 14 when a decreasing distance from the position determined by the geocoordinates is detected from the position of the mobile computer system 14. In addition, in the course of activation, a navigation function may be triggered, which guides the user specifically to the position specified by the geocoordinates.

In a third step S3, field information based on the specific data recording are received. The data recording is apparent here from the information protocol. For instance, geocoordinates of the reference or trial field may be detected. The geocoordinates of the position where the user is present on execution of the application of the invention are preferably recorded automatically by means of a GPS sensor which is included nowadays in most smartphones. It is also conceivable that the user records his position on a virtual map.

In addition, data relating to the crop may be recorded. The user may be asked here to specify the crop plant being grown in a reference or trial field (plant type). It is conceivable that this information is displayed in machine-readable form, for example on an information sign in the field. It is conceivable, for example, that the information about the crop plant being grown in each case is available in the form of an optical code (for example a barcode, data matrix code, QR code or comparable code). In such a case, it is conceivable that the user, for example, will use a smartphone to read the optical code by means of the installed camera function and to transmit the information to the application of the invention. It is also conceivable that the user is asked to take a photograph of the crop (for example of a single plant). It is conceivable that the particular crop is detected automatically with the aid of image analysis and object recognition methods. It is conceivable that the automatic recognition by means, for example, of image analysis and object recognition methods is conducted on the user's mobile computer system; it is likewise conceivable that the photographic image is transmitted to an external server, for example by means of the mobile communication network, and analyzed thereon. It is conceivable that the result of the analysis is transmitted to the user.

In addition, data relating to the sowing date or soil may be recorded. The sowing date can be input by the user, read in from an external source, for example via an information sign with optical code or via an RFID tag, or ascertained automatically from the growth stage of the plant from a photographic image with the aid of image analysis methods. The type of soil present and the soil conditioning measures conducted are preferably likewise requested/ascertained by the application of the invention.

In addition, data relating to the history may be recorded. It may also be advantageous to find out information about the previous history of the reference or trial field, for example which plants have been grown before and/or which crop protection measures have been undertaken before. These data can be requested from the user or adduced at a later juncture from other sources (for example if the information has already been transmitted to an external server).

In addition, data relating to the growth stage may be recorded. The growth stage of the plants being grown in the reference or trial field can be input by the user or ascertained automatically from a photographic image with the aid of image analysis methods.

In addition, data relating to harmful organisms may be recorded. For the optimization and/or calibration and/or further development of the prediction tool, a matter of particular interest is whether a harmful organism has already spread in the reference or trial field and, if so, to what extent it has already spread. The application thus preferably asks and/or ascertains whether a harmful organism is apparent, which harmful organism it is, how severely the plants have already been affected and how the harmful organism has spread/is spreading (for example in the form of clusters or proceeding from a particular field boundary or the like). This information can also be ascertained using photographic images, for example in order to use image analysis and object recognition methods to recognize a harmful organism present and/or to estimate/quantify the severity of an attack.

In a fourth step S4, the field information received is transmitted to the server 12 and can be used for calibration or optimization of the forecasting models.

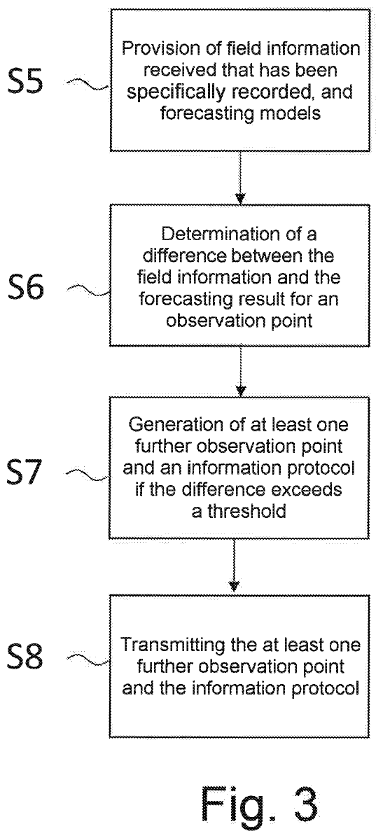

FIG. 3 shows an illustrative method of calibrating and optimizing forecasting models based on field information that has been recorded specifically.

In a first step S5, field information is provided, which has been recorded specifically by the method described above. For example, the field information for a geocoordinate at a time that can be correlated via the BBCH code to the morphological growth stage of the crop plant may comprise information relating to pest attack. This is transmitted from the mobile computer system 14 to the server 12.

In a second step S6, the forecasting models are verified or falsified based on the field information provided. For this purpose, a difference between the field information and the result of the forecast is determined for an observation point. For example, the result of the forecasting model relating to pest attack for the geocoordinate communicated and the time communicated can be compared with the field information recorded relating to pest attack.

In a third step S7, at least one further observation point and a corresponding information protocol are generated if the difference exceeds a threshold. In a fourth step S8, the observation points and information protocols generated are communicated to one or more mobile computer system(s) 14. For instance, it is possible to specifically record further field information with which the forecasting model can be further developed and improved.

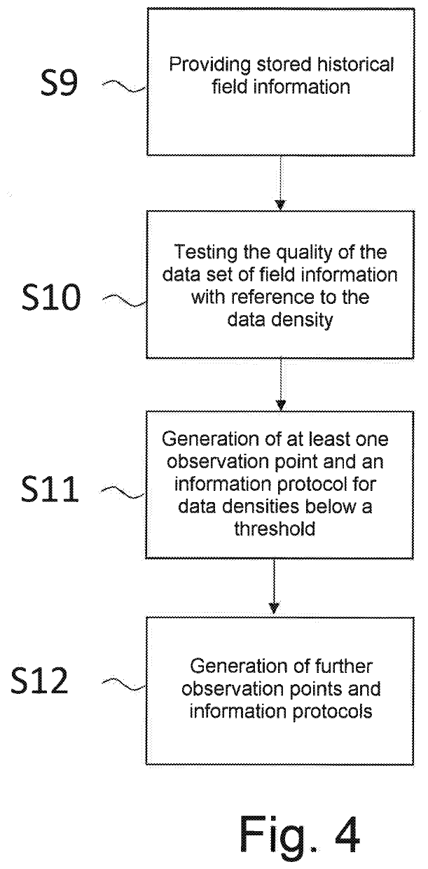

FIG. 4 shows a further illustrative method of calibrating and optimizing forecasting models based on field information that has been recorded specifically or nonspecifically.

In a first step S9, historical field information is provided. Such field information may be stored on the server 12 or in a separate database 24 accessed by the server 12.

In a second step S10, the quality of the data set is verified by verifying field information for the quality of the data set. For example, the field information stored can be verified with regard to the amount of data for different geocoordinates, growth stages or weather conditions.

In a third step S11, at least one further observation point and a corresponding information protocol are generated if the difference exceeds a threshold. In a fourth step S12, the observation points and information protocols generated are communicated to one or more mobile computer system(s) 14. For instance, it is possible to specifically record further field information with which the forecasting model can be further developed and improved.

1.-23. (canceled)

24. A method of calibrating and/or optimizing forecasting models, comprising the steps of
providing an application for a mobile computer system for a multitude of users involved in one or more field trials for crop protection products,
users searching for reference fields or trial fields and recording field information,
users transmitting field information about the reference fields or trial fields, about crop plants grown in the reference fields or trial fields and any harmful organisms present with the aid of the application to a server belonging to a supplier of forecasts of the attack on crop plants by harmful organisms on the basis of forecasting models,
correlating the field information transmitted with further data,
calibrating and/or optimizing the forecasting models on the basis of the field information transmitted and further data used for correlation.

25. The method according to claim 24, further comprising the step of
transmitting optimized forecasts based on the optimized and/or calibrated forecasting model.

26. The method according to claim 24, wherein the field information transmitted comprises one or more items of information from the following list: geocoordinates of the reference or trial field, time of information transmission, crop grown, sowing date of the crop grown, stage of growth of the crop grown, attack on the crop grown by a harmful organism.

27. The method according to claim 26, wherein geocoordinates of a reference or trial field for user searching for reference or trial fields are provided on the mobile computer system, and reference or trial fields are additionally searched for in a guided manner with the aid of geocoordinates.

28. The method according to claim 24, wherein field information is recorded in a specific or nonspecific manner, with transmittance of the field information by the mobile computer system to the server immediately after the recording of the field information.

29. A system for calibrating and/or optimizing forecasting models, comprising
a mobile computer system, and
a server,
wherein the mobile computer system. is configured such that it assists a user of the mobile computer system in collecting the following field information:
location of a reference or trial field,
crop plants grown in the reference or trial field,
the nature and extent of harmful organisms that exist in the crop plants at one time, with configuration of the mobile computer system such that it transmits the field information collected to the server,
wherein the server is configured to correlate the field information transmitted with further data.

30. The system according to claim 29, configured in such a way that it uses the data transmitted and the further data to calibrate and/or optimize a forecasting model for the spread of harmful organisms.

31. A computer program product comprising a computer-readable data storage medium and program code which is stored on the data storage medium and, on execution on a mobile computer system, causes the mobile computer system to execute the following steps:
ascertaining field information about
the location of a reference or trial field
crop plants grown in the reference or trial field
the attack on the crop plants by a harmful organism at one time transmitting the field information to a server.

32. A method of specific recording of field information with the aid of a mobile computer system, comprising the steps of:
a) providing (S1) at least one observation point and at least one information protocol assigned to the observation point,
b) activating (S2) a specific recording of data based on the information protocol,
c) recording (S3) field information based on the specific data recording according to the information protocol, and
d) providing (S3) the field information recorded to a server.

33. The method according to claim 32, wherein the observation point specifies geocoordinates and time data.

34. The method according to claim 32, wherein the activation (S2) is effected on the basis of the observation point and/or the corresponding information protocol.

35. The method according to claim 32, wherein the activation (S2) comprises a navigation function that uses position data from the mobile computer system to generate a navigation path to the observation point,

36. The method according to claim 32, wherein the field information is recorded (S3) by readout of an optical code or a transponder with the aid of the mobile computer system or the field information is recorded (S3) by provision of a photographic image with the aid of the mobile computer system and the field information is extracted by means of an image analysis method.

37. A method of calibrating and/or optimizing forecasting models, comprising the steps of:
a) providing (S5) an item of field information that has been recorded in a specific manner with reference to an observation point and an information protocol assigned to the observation point,
b) providing (S5) a result from a forecasting model based on the observation point,
c) determining (S6) a difference between the field information assigned to the observation point and the result from the forecasting model based on the observation point,
d) generating (S7) at least one further observation point and an information protocol assigned to the further observation point if the difference exceeds a threshold, and
e) providing (S8) the at least one further observation point and the information protocol assigned to the further observation point to at least one mobile computer system.

38. The method according to claim 37, wherein the difference determined between the field information assigned to the observation point and the result from the forecasting model based on the observation point is used to determine a prediction accuracy.

39. A method of calibrating and/or optimizing forecasting models, comprising the steps of:
a) providing (S9) field information,
b) determining (S10) a data density of the field information for multiple classes of field information,
c) generating (S11) at least one observation point and an information protocol assigned to the observation point for the class of field information for which the data density is below a threshold, and
d) providing (S12) the at least one observation point and the information protocol assigned to the observation point to at least one mobile computer system.

40. The method according to claim 37, wherein the observation point is determined on the basis of reference or trial field data.

41. A method of generating a forecast relating to field information, field conditions or relating to recommendation of agricultural measures, comprising the steps of:
a) recording field information, where the field information is recorded in a nonspecific or specific manner by the method according to claim 32, and which optionally, in the case of specific recording, optimizes and/or calibrates forecasting models, followed by specific recording of field information by the method according to claim 32,
b) updating the forecasting model based on the field information recorded, where the forecasting model is updated at regular or irregular time intervals, especially during a growing period, based on the field information recorded, and
c) generating a forecast based on the updated forecasting model.

42. A computer program product with program instructions stored on a machine-readable storage medium, wherein one of the methods according to claim 24 is executed when the program instructions are executed on one or more computer(s).

43. A mobile computer system for specific recording of field information, comprising:
a) an interface configured to provide at least one observation point and at least one information protocol assigned to the observation point,
b) an activation module configured to activate specific collection of data on the basis of the information protocol,
c) a recording module configured to record field information on the basis of the specific data recording according to the information protocol, and
d) a further interface configured to transmit the field information received to a server.

44. A system for calibrating and/or optimizing forecasting models, comprising:
a) an interface configured to provide an item of field information that has been recorded in a specific manner with reference to an observation point and an information protocol assigned to the observation point,
b) a forecasting module configured provides a result of a forecasting model based on the observation point,
c) a verification module configured to determine a difference between the field information assigned to the observation point and the result from the forecasting model based on the observation point,
d) a generation module configured to generate at least one further observation point and an information protocol assigned to the further observation point if the difference exceeds a threshold, and
e) a further interface configured to transmit the at least one further observation point and the information protocol assigned to the further observation point to at least one mobile computer system.

45. A system for calibrating and/or optimizing forecasting models, comprising the steps of:
a) an interface configured to provide field information,
b) a verification module configured to determine a data density of the field information for multiple classes of field information,
c) a generation module configured to generate at least one observation point and an information protocol assigned to the observation point for the class of field information for which the data density is below a threshold, and
d) a further interface configured to transmit the at least one observation point and the information protocol assigned to the observation point to at least one mobile computer system.

46. A system for generating a forecast relating to field information, field conditions or relating to recommendation of agricultural measures, comprising:
a) a mobile computer system configured to record an item of field information nonspecifically or specifically by the method according to claim 32,
b) optionally, in the case of specific or nonspecific recording, a system (12) for optimizing and/or calibrating forecasting models, configured to optimize and/or calibrate the forecasting model and to trigger specific recording of field information by the method according to claim 32, and
c) a system for updating the forecasting model, configured to update the forecasting model at regular or irregular time intervals, especially during a growing period, on the basis of the field information recorded and to generate a forecast on the basis of the updated forecasting model.
